(19) United States
(12) Patent Application Publication
(10) Pub. No.: US 2004/0170060 A1
(43) Pub. Date: Sep. 2, 2004

(54) Semiconductor storage device preventing data change due to accumulative disturbance

(75) Inventor: Shinichi Ishimoto, Tokyo (JP)

Correspondence Address: BURNS DOANE SWECKER & MATHIS L L P, POST OFFICE BOX 1404, ALEXANDRIA, VA, 22313-1404, US

(73) Assignees: RENESAS TECHNOLOGY CORP.; RENESAS SOLUTIONS CORPORATION

(21) Appl. No.: 10/644,910

(22) Filed: Aug. 21, 2003

(30) Foreign Application Priority Data
Feb. 27, 2003 (JP) 2003-051203 (P)

(51) Int. Cl. G11C 11/34

(52) U.S. Cl. 365/185.25

(57) ABSTRACT

A refresh zone detection part divides a block of a semiconductor memory into refresh zone units for executing refresh, and detects the refresh zone including the sector of the writing target. A refresh execution part sequentially refreshes the sectors included in the refresh zone detected by refresh zone detection part, every time data is written to a sector. Thus, it is possible to prevent the number of rewritings to a specific sector from increasing, and the refresh can prevent data change due to accumulative disturbance.

### BACKGROUND OF THE INVENTION

1. Field of the Invention

The present invention relates to a semiconductor storage device with a semiconductor memory to which data is written in sector units and, more particularly, to a semiconductor storage device preventing data change due to accumulative disturbance.

2. Description of the Background Art

In recent years, large-capacity memories are in increasing demand and nonvolatile memories have come into widespread use. In general, a nonvolatile memory is formed of a plurality of blocks and each block is formed of a plurality of sectors.

When data is written to/erased from a sector, the other sectors in the same block are also applied with voltage because the application of voltage is performed block by block. This application of voltage has a slight influence on the other sectors (hereinafter, the influence is referred to as disturbance).

With the accumulation of disturbance, the electric charge held in each memory cell is gradually lost so as to shorten the data storage time. To be more specific, in the same block, a sector to which no data has been written has accumulative disturbance due to a sector to which data has been written, and when the number of disturbances exceeds the predetermined number of times, data changes. There would be no serious problem when the predetermined number of times is larger than the number of rewritings of the nonvolatile memory; however, there is a problem because the predetermined number of times is smaller than the number of rewritings of the nonvolatile memory.

In order to prevent data change due to such accumulative disturbance, it is necessary to gather sectors to which no data is written at a specific block or to manage the number of rewritings in sector units. It is also possible to prevent data change due to accumulative disturbance by executing a refresh operation in which data is read from a memory cell and the same data is rewritten again. Japanese Patent Laying-Open No. 6-215584 discloses an invention related to this art.

In a nonvolatile semiconductor storage device disclosed in Japanese Patent Laying-Open No. 6-215584, the refresh control circuit reads data stored in a 1024-bit flag cell array, starting at the first piece, and when the first flag cell in the erased state is reached, puts the flag cell into the written state and refreshes the nonvolatile memory of the corresponding refresh block.

When the final flag cell is reached as the result of the sequential reading of the data stored in the flag cell array, an erasing operation is performed in order to put all the flag cells in the erased state. This enables the flags to be erased in one operation according to 1024 refreshes, making it possible to prevent the concentration of writing/erasing when the refresh counter is formed of nonvolatile memory.

As described above, data change due to accumulative disturbance can be prevented by gathering sectors to which no data is written at a specific block, or managing the number of rewritings in sector units. However, this has the problem that complicated management decreases the processing efficiency of the semiconductor storage device.

In the nonvolatile memory disclosed in Japanese Patent Laying-Open No. 6-215584, the refresh of 1024 refresh blocks is managed by the 1024-bit flag cell array so as to prevent the concentration of writing/erasing which is caused when the refresh counter is formed of a nonvolatile memory. However, there is no consideration about the degree of accumulation of disturbance in the other sectors in the same block. Thus refreshing all the blocks uniformly causes the problem of decreasing the processing efficiency and increasing the number of writings.

### SUMMARY OF THE INVENTION

An object of the present invention is to provide a semiconductor storage device preventing data change due to accumulative disturbance while suppressing the increase in the number of rewritings to a sector.

According to an aspect of the present invention, a semiconductor storage device includes: a nonvolatile memory to which data is written in a sector unit; and a data rewriting unit rewriting data in the nonvolatile memory, wherein each sector in the nonvolatile memory includes: a data area into which data is stored; and a refresh mark into which information indicative of whether refresh has been performed or not is stored, and the data rewriting unit includes a refresh execution unit referring to the refresh mark and determining whether the sector is refreshed or not, thereby executing the refresh.

Since the refresh execution unit refers to the refresh mark and determines whether the sector is refreshed or not, thereby executing the refresh, it is possible to prevent the number of rewritings to a specific sector from increasing, and data change due accumulative disturbance can be prevented by the refresh.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram showing the schematic configuration of a semiconductor storage device according to a first embodiment of the present invention;

FIG. 2 is a diagram showing an example of the data structure of a sector in a semiconductor memory 2;

FIG. 3 is a block diagram showing the schematic configuration of semiconductor memory 2 according to the first embodiment of the present invention;

FIG. 4 is a diagram for describing logical/physical sector conversion;

FIG. 5 is a block diagram showing the functional structure of a data rewriting unit according to the first embodiment of the present invention;

FIG. 6 is a flowchart for describing the operation procedure of the semiconductor storage device according to the first embodiment of the present invention;

FIG. 7 is a flowchart for describing the operation procedure of a semiconductor storage device according to a second embodiment of the present invention;

FIG. 8 is a flowchart for describing the operation procedure of a semiconductor storage device according to a third embodiment of the present invention;

FIG. 9 is a flowchart for describing the operation procedure of a semiconductor storage device according to a fourth embodiment of the present invention;

FIG. 10 is a flowchart for describing the operation procedure of a semiconductor storage device according to a fifth embodiment of the present invention;

FIG. 11 is a flowchart for describing the operation procedure of a semiconductor storage device according to a sixth embodiment of the present invention;

### DESCRIPTION OF THE PREFERRED EMBODIMENTS

First Embodiment

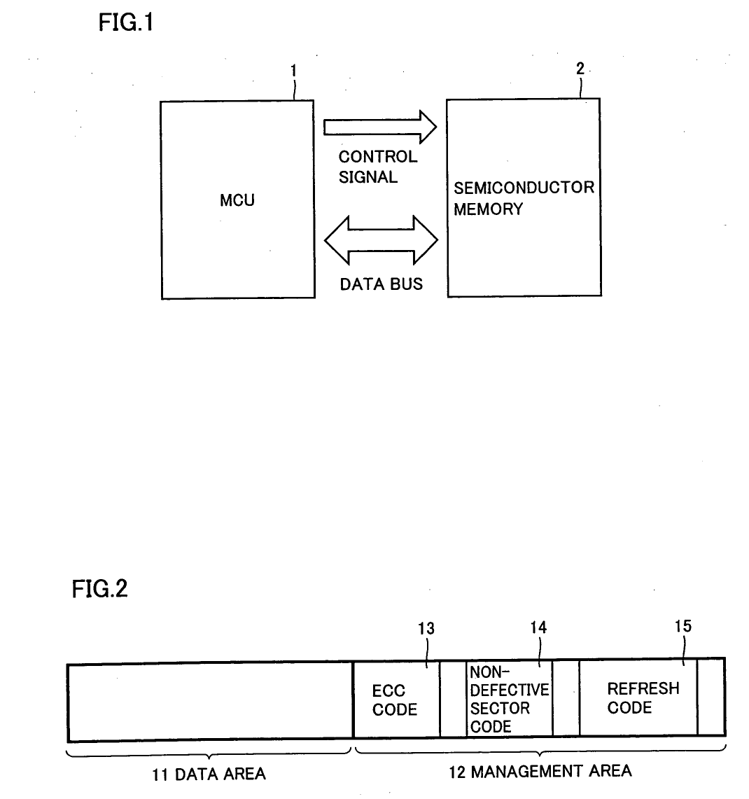

FIG. 1 is a block diagram showing the schematic configuration of a semiconductor storage device according to a first embodiment of the present invention. This semiconductor storage device includes an MCU (Micro Controller Unit) 1 which controls the whole semiconductor storage device and a semiconductor memory 2 formed of a nonvolatile memory and the like.

MCU1 is formed of CPU (Central Processing Unit), RAM (Random Access Memory) and other components, and controls semiconductor memory 2 by making the CPU execute a program stored in the RAM or other units. MCU 1 controls the reading/writing of data from/to semiconductor memory 2 by a control signal. The reading/writing of data is carried out via a data bus.

FIG. 2 is a diagram showing an example of the data structure of a sector in semiconductor memory 2. Each sector includes a data area 11 and a management area 12. Management area 12 includes an ECC (Error Checking and Correcting) code 13 for error detection/correction of data area 11, a non-defective sector code 14 indicating whether the sector is non-defective or defective, and a refresh mark 15 indicating whether refresh has been performed or not.

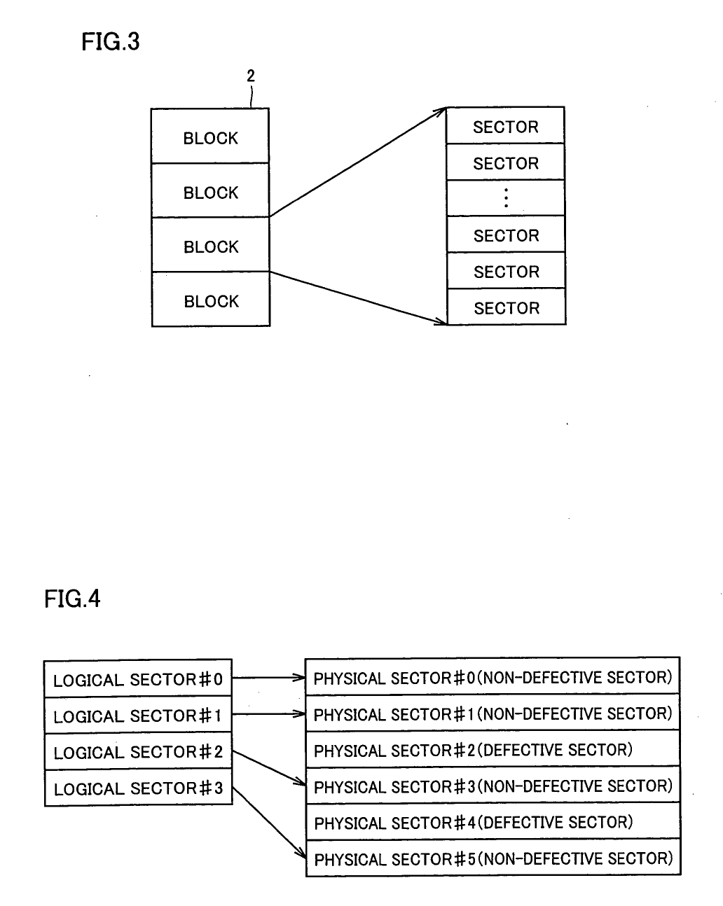

FIG. 3 is a block diagram showing the schematic configuration of semiconductor memory 2 according to the first embodiment of the present invention. Semiconductor memory 2 is formed of a plurality of blocks and each block is formed of a plurality of sectors.

When semiconductor memory such as nonvolatile memory as shown in FIG. 3 is used, not all sectors are non-defective in some cases, so it is necessary to make sure that a logical address is assigned only to a non-defective sector. A non-defective sector assigned with a logical address is referred to as a logical sector; non-defective and defective sectors are collectively referred to as physical sectors; and the conversion from the address (number) of a logical sector into the address (number) of a physical sector is hereinafter referred to as logical/physical sector conversion.

FIG. 4 is a diagram for describing the logical/physical sector conversion. While excluding physical sectors #2 and #4 which are defective, a physical sector #0 is assigned with logical sector #0; a physical sector #1 is assigned with logical sector #1; a physical sector #3 is assigned with logical sector #2; and a physical sector #5 is assigned with logical sector #3. Information about the logical/physical sector conversion is managed by being written into a specific sector. The information about the logical/physical sector conversion is transferred to the above-mentioned RAM and referred to by the CPU.

When the writing/erasing of data becomes impossible because of the deterioration of a logical sector, the CPU assigns the logical sector number to another physical sector number and updates the information about the logical/physical sector conversion. The updated information about the logical/physical sector conversion is reflected on the RAM and the above-mentioned specific sector.

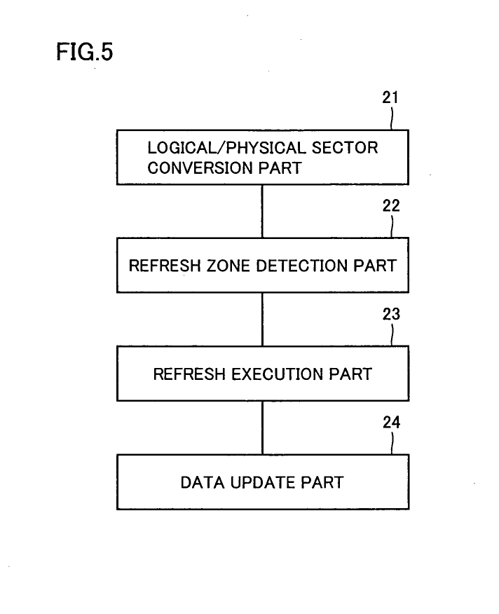

FIG. 5 is a block diagram showing the functional configuration of the data rewriting function (hereinafter, referred to as a data rewriting unit) which is realized by the execution of a program by MCU1 according to the first embodiment of the present invention. The data rewriting unit includes a logical/physical sector conversion part 21 which performs a conversion from a logical sector into a physical sector; a refresh zone detection part 22 which detects one or more blocks which are to be the refresh target (hereinafter, referred to as refresh zone); a refresh execution part 23 which refreshes a sector included in the refresh zone; and a data update part 24 which performs a data update in the target sector.

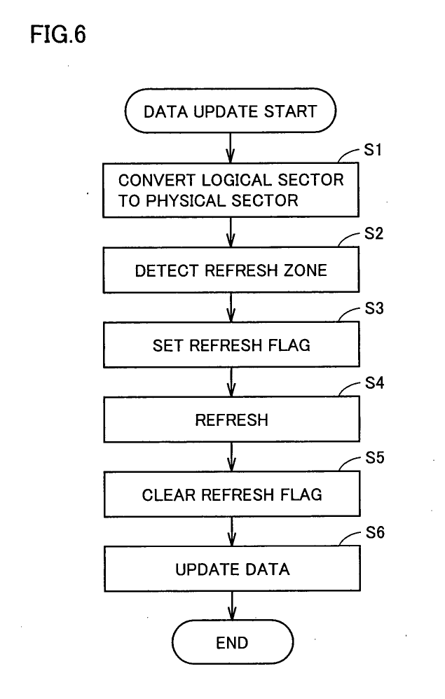

FIG. 6 is a flowchart for describing the operation procedure of the semiconductor storage device according to the first embodiment of the present invention. When data is written to a logical sector, logical/physical sector conversion part 21 converts the logical sector into a physical sector (S1).

Then, refresh zone detection part 22 detects a refresh zone that is the refresh target on the basis of the physical sector number converted by logical/physical sector conversion part 21 (S2).

Refresh execution part 23 sets a refresh flag (S3), detects and refresh one sector in the refresh zone that is the refresh target, and updates the contents of refresh mark 15 of this sector (S4). The refresh in the present embodiment involves the rewriting of information (the writing of the same contents) in the sectors, starting at the head sector within the refresh zone, without considering the number of rewritings. The rewriting, which is performed prior to the change of data due to accumulative disturbance caused by writing data into a sector, enables the electric charge held in each memory cell to be recharged, thereby preventing data change.

For example, in the case where data in the sector which has not undergone data writing is changed by accumulative disturbance when 100000 times of writings have been performed for one block, all the sectors can be refreshed while performing 100000 times of writings for one block in order to prevent data change.

The update of the contents of refresh mark 15 is carried out by writing “55” in the first round of refresh to the refresh mark in the sector which has been refreshed; writing “AA” in the second round of refresh to the refresh mark in the sector which has been refreshed; and writing these values alternately hereafter. A refresh execution part 23 detects a site where the refresh mark of a sector in the refresh zone changes from “55” to “AA” or from “AA” to “55”, thereby detecting how far the sectors has been refreshed.

When refresh has been completed, refresh execution part 23 clears the refresh flag (S5). Then, data update part 24 writes data to the sector of the data writing target (S6) and finishes the processing. The refresh flag is referred to in order to determine whether the sector is being refreshed or not.

In steps S3 to S5, when the sector of the data writing target is the same as the sector of the refresh target, it is sufficient only to update the data (S6), without refreshing the sector.

As described above, according to the semiconductor storage device of the present embodiment, when data is written to a sector, a refresh zone is detected from the sector, and the sectors in the refresh zone are refreshed one at a time. Therefore, when there is the same number of data writings as the number of sectors included in the refresh zone, each sector is surely refreshed one time, which can prevent data change due to accumulative disturbance.

In addition, each sector is provided with refresh mark 15; the contents of refresh mark 15 are updated during refresh; and the sector of the refresh target is searched by referring to the refresh mark. This has eliminated the need for the provision of a refresh counter, so that it is possible to prevent the concentration of writing/erasing which would be caused when the refresh counter is formed of a nonvolatile memory.

Second Embodiment

In the first embodiment of the present invention, every time data is written to one sector, one sector is refreshed. This deteriorates writing efficiency and is likely to accelerate to reach the upper limit of the number of rewritings of semiconductor memory 2 because of frequent refresh. A semiconductor storage device according to a second embodiment of the present invention is improved in this aspect.

The semiconductor storage device of the present embodiment has the same schematic configuration as the semiconductor storage device according to the first embodiment shown in FIG. 1. A data rewriting unit according to the present embodiment differs from the data rewriting unit according to the first embodiment shown in FIG. 5 in the functions of refresh zone detection part 22 and refresh execution part 23. Therefore, their configuration and features already described in detail above will not be repeated. The refresh zone detection part and the refresh execution part in the present embodiment will be referred to with reference numerals 22a and 23a, respectively.

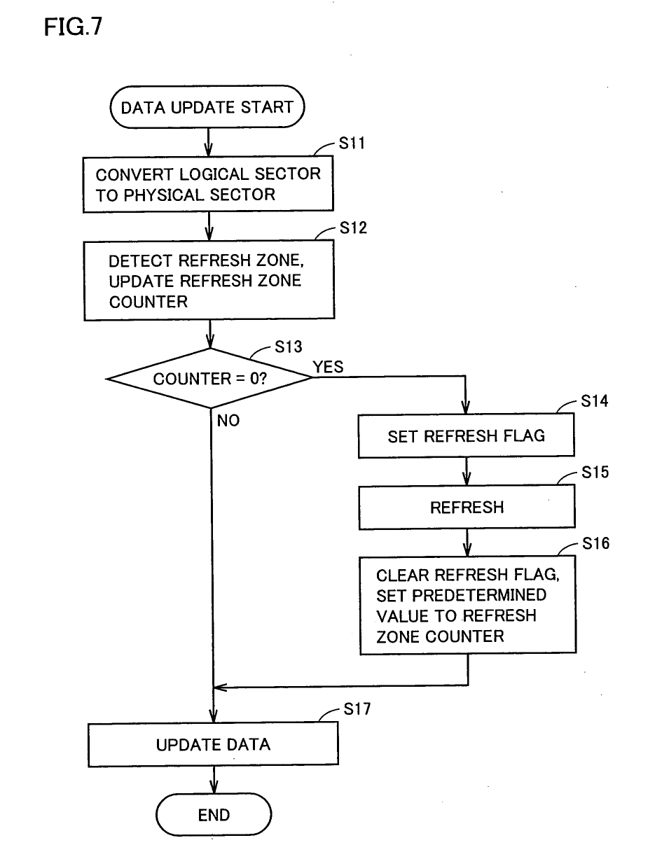

FIG. 7 is a flowchart for describing the operation procedure of the semiconductor storage device according to the second embodiment of the present invention. When data is written to a certain logical sector, logical/physical sector conversion part 21 converts the logical sector into a physical sector (S11).

Refresh zone detection part 22a detects a refresh zone which is to be the refresh target on the basis of the physical sector number converted by logical/physical sector conversion part 21, and decrements the value of the refresh zone counter corresponding to the refresh zone (S12).

Refresh zone counters are provided to respective refresh zones, and the values of these counters are stored in the RAM. At the time of initial setting, refresh zone detection part 22a sets a predetermined value in a refresh zone counter. When data is written to a sector, refresh zone detection part 22a decrements the value of the refresh zone counter corresponding to the refresh zone including the sector.

Then, refresh execution part 23a determines whether the value of the refresh zone counter is “0” or not (S13). When the value of the refresh zone counter is not “0” (S13, No), no refresh is performed, and data update part 24 writes data to the sector (S17) to finish the processing.

When the value of the refresh zone counter is “0” (S13, Yes), refresh execution part 23a sets a refresh flag (S14), detects and refreshes one sector in the refresh zone which is to be the refresh target, and updates the contents of refresh mark 15 of this sector (S15). In the refresh of the present embodiment, every time data is written to a sector for a predetermined number of times, the information in the sectors in the refresh zone is rewritten sector by sector, starting at the head sector.

When the refresh has been completed, refresh execution part 23a clears the refresh flag, and sets a predetermined value in the refresh zone counter (S16). Data update part 24 writes data to the sector of the data writing target (S17) and finishes the processing.

In steps S14 to S16, when the sector of the data writing target and the sector of the refresh target are the same, it is sufficient only to update the contents of refresh mark 15 and the data of the sector (S17), without refreshing this sector.

As described above, according to the semiconductor storage device of the present embodiment, when data is written to a sector, a refresh zone is detected from the sector, and every time data is written to a sector in the refresh zone for a predetermined number of times, one sector in the refresh zone is refreshed. As a result, in addition to the effects described in the first embodiment, it also becomes possible to reduce refreshes, thereby deferring to reach the upper limit of rewriting of semiconductor memory 2.

Third Embodiment

A semiconductor storage device according to the present embodiment has the same schematic configuration as the semiconductor storage device according to the first embodiment shown in FIG. 1. A data rewriting unit according to the present embodiment differs from the data rewriting unit according to the first embodiment shown in FIG. 5 in the functions of refresh zone detection part 22 and refresh execution part 23. Therefore, their configuration and features already described in detail above will not be repeated. The refresh zone detection part and the refresh execution part in the present embodiment will be referred to with reference numerals 22b and 23b, respectively.

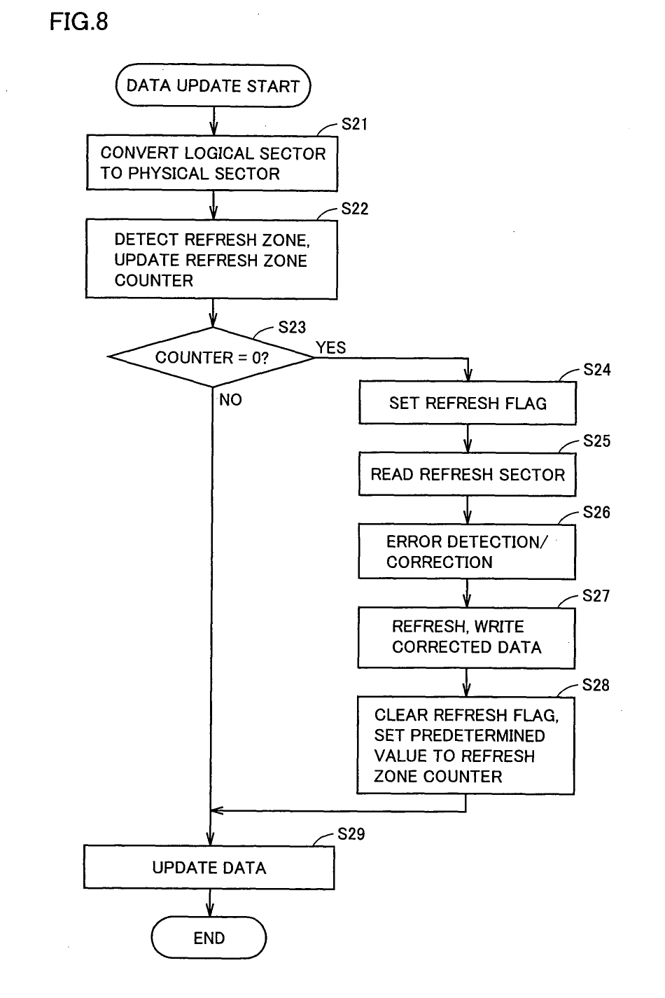

FIG. 8 is a flowchart for describing the operation procedure of the semiconductor storage device according to the third embodiment of the present invention. When data is written to a certain logical sector, logical/physical sector conversion part 21 converts the logical sector into a physical sector (S21).

Then, refresh zone detection part 22b detects a refresh zone which is to be the refresh target on the basis of the physical sector number converted by logical/physical sector conversion part 21, and decrements the value of the refresh zone counter corresponding to the refresh zone (S22).

Refresh execution part 23b determines whether the value of the refresh zone counter is “0” or not (S23). When the value of the refresh zone counter is not “0” (S23, No), no refresh is performed. Data update part 24 writes data to the sector (S29) to finish the processing.

When the value of the refresh zone counter is “0” (S23, Yes), refresh execution part 23b sets a refresh flag (S24), detects one sector in the refresh zone which is to be the refresh target, and reads ECC code 13 as well as data from the sector (S25).

Refresh execution part 23b performs error detection/correction of data by using ECC code 13 (S26), and refreshes the sector by writing the corrected data to the same sector (S27).

When the refresh has been completed, refresh execution part 23b clears the refresh flag, and sets a predetermined value in the refresh zone counter (S28). Data update part 24 writes data to the sector of the data writing target (S29) to finish the processing.

In steps S24 to S28, when the sector of the data writing target and the sector of the refresh target are the same, it is sufficient only to update the contents of refresh mark 15 and the data of the sector (S29), without refreshing this sector.

As described above, according to the semiconductor storage device of the present embodiment, every time data is written to a sector in the refresh zone for a predetermined number of times, the data in one sector in the refresh zone is subjected to error detection/correction and then the corrected data is written to the same sector. Consequently, in addition to the effects described in the second embodiment, it also becomes possible to perform error detection/correction of data, even when some of the data has been changed due to accumulative disturbance.

Fourth Embodiment

A semiconductor storage device according to the present embodiment has the same schematic configuration as the semiconductor storage device according to the first embodiment shown in FIG. 1. A data rewriting unit according to the present embodiment differs from the data rewriting unit according to the first embodiment shown in FIG. 5 in the functions of refresh zone detection part 22 and refresh execution part 23. Therefore, their configuration and features already described in detail above will not be repeated. The refresh zone detection part and the refresh execution part in the present embodiment will be referred to with reference numerals 22c and 23c, respectively.

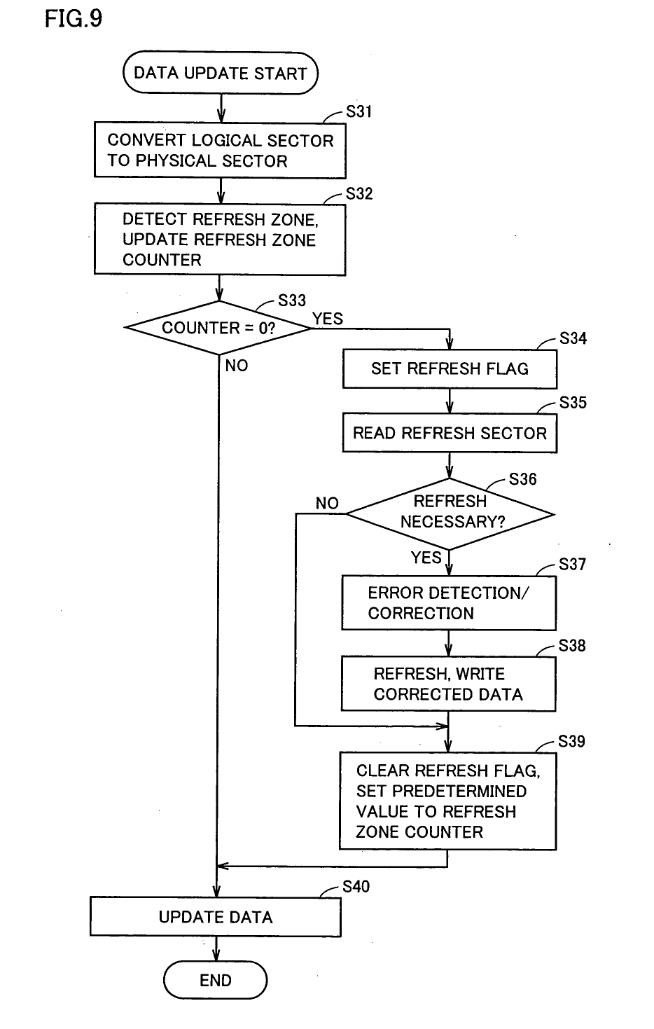

FIG. 9 is a flowchart for describing the operation procedure of the semiconductor storage device according to the fourth embodiment of the present invention. First, when data is written to a certain logical sector, logical/physical sector conversion part 21 converts the logical sector into a physical sector (S31).

Then, refresh zone detection part 22c detects a refresh zone which is to be the refresh target on the basis of the physical sector number converted by logical/physical sector conversion part 21, and decrements the value of the refresh zone counter corresponding to the refresh zone (S32).

Refresh execution part 23c determines whether the value of the refresh zone counter is “0” or not (S33). When the value of the refresh zone counter is not “0” (S33, No), no refresh is performed. Data update part 24 writes data to the sector (S40) to finish the processing.

When the value of the refresh zone counter is “0” (S33, Yes), refresh execution part 23c sets a refresh flag (S34), detects one sector in the refresh zone which is to be the refresh target, and reads ECC code 13 as well as data from the sector (S35).

Then, refresh execution part 23c reads non-defective sector code 14 from the same sector, and determines whether the sector needs refresh or not, depending on whether the sector is defective or not (S36).

When the sector does not need refresh (S36, No), the process proceeds to step S39. On the other hand, when the sector needs refresh (S36, Yes), refresh execution part 23c performs error detection/correction of data by using ECC code 13 (S37), and refreshes the sector by writing the corrected data to the same sector (S38).

When the refresh has been completed, refresh execution part 23c clears the refresh flag, and sets a predetermined value in the refresh zone counter (S39). Data update part 24 writes data to the sector of the data writing target (S40) to finish the processing.

In steps S34 to S39, when the sector of the data writing target and the sector of the refresh target are the same, it is sufficient only to update the contents of refresh mark 15 and the data of the sector (S40), without refreshing this sector.

As described above, according to the semiconductor storage device of the present embodiment, every time data is written to a sector in the refresh zone for a predetermined number of times, it is determined whether one sector in the refresh zone is defective or not, and only when the sector has been determined not to be defective, error detection/correction of data is performed so as to write the corrected data to the same sector. Consequently, in addition to the effects described in the third embodiment, it also becomes possible to prevent a defective sector from being refreshed, thereby improving the processing efficiency.

Fifth Embodiment

A semiconductor storage device according to the present embodiment has the same schematic configuration as the semiconductor storage device according to the first embodiment shown in FIG. 1. A data rewriting unit according to the present embodiment differs from the data rewriting unit according to the first embodiment shown in FIG. 5 in the functions of refresh zone detection part 22 and refresh execution part 23. Therefore, their configuration and features already described in detail above will not be repeated. The refresh zone detection part and the refresh execution part in the present embodiment will be referred to with reference numerals 22d and 23d, respectively.

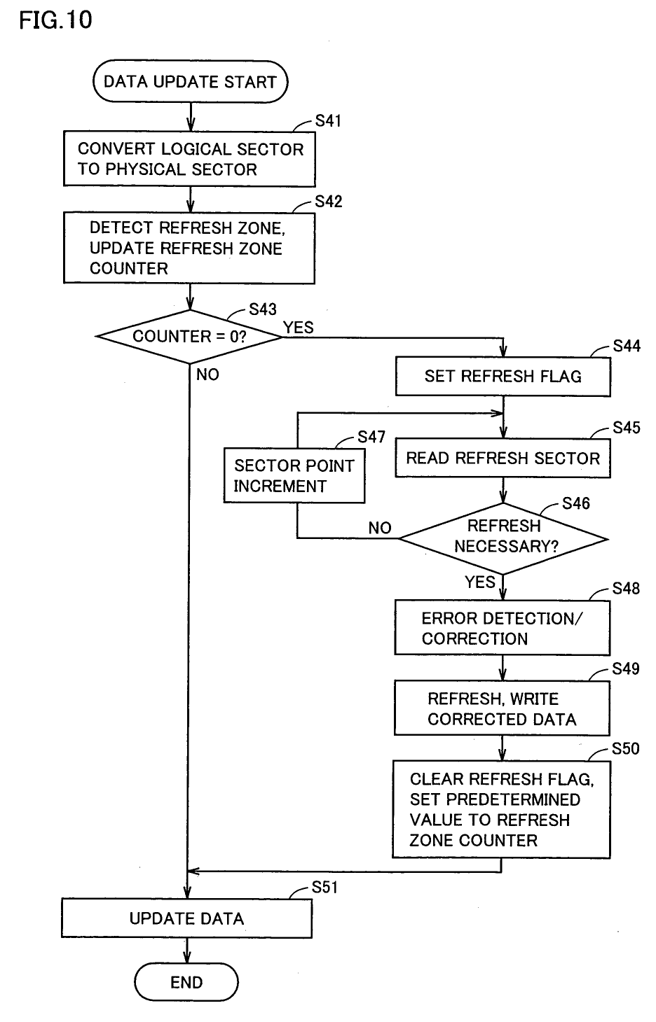

FIG. 10 is a flowchart for describing the operation procedure of the semiconductor storage device according to the fifth embodiment of the present invention. First, when data is written to a certain logical sector, logical/physical sector conversion part 21 converts the logical sector into a physical sector (S41).

Then, refresh zone detection part 22d detects a refresh zone which is to be the refresh target on the basis of the physical sector number converted by logical/physical sector conversion part 21, and decrements the value of the refresh zone counter corresponding to the refresh zone (S42).

Refresh execution part 23d determines whether the value of the refresh zone counter is “0” or not (S43). When the value of the refresh zone counter is not “0” (S43, No), no refresh is performed. Data update part 24 writes data to the sector (S51) to finish the processing.

When the value of the refresh zone counter is “0” (S43, Yes), refresh execution part 23d sets a refresh flag (S44), detects one sector in the refresh zone which is to be the refresh target, and reads ECC code 13 as well as data from the sector (S45).

Then, refresh execution part 23d reads non-defective sector code 14 from the same sector, and determines whether the sector needs refresh or not, depending on whether the sector is defective or not (S46).

When the sector does not need refresh (S46, No), the sector pointer is incremented (S47), and the process returns to step S45 to repeat the subsequent procedure. This sector pointer indicates the sector of the refresh target, and is sequentially incremented until the number of the sectors in the refresh zone is reached. When the sector pointer reaches the number of the sectors in the refresh zone, the value of the sector pointer is initialized.

When the sector needs refresh (S46, Yes), refresh execution part 23d performs error detection/correction of data by using ECC code 13 (S48), and refreshes the sector by writing the corrected data to the same sector (S49).

When the refresh has been completed, refresh execution part 23d clears the refresh flag, and sets a predetermined value in the refresh zone counter (S50). Data update part 24 writes data to the sector of the data writing target (S51) to finish the processing.

In steps S44 to S50, when the sector of the data writing target and the sector of the refresh target are the same, it is sufficient only to update the contents of refresh mark 15 and the data of the sector (S51), without refreshing this sector.

As described above, according to the semiconductor storage device of the present embodiment, every time data is written to a sector in the refresh zone for a predetermined number of times, it is determined whether one sector in the refresh zone is defective or not, and when the sector has been determined to be defective, the next sector is refreshed. Consequently, in addition to the effects described in the fourth embodiment, it also becomes possible to further improve the processing efficiency.

Sixth Embodiment

A semiconductor storage device according to the present embodiment has the same schematic configuration as the semiconductor storage device according to the first embodiment shown in FIG. 1. A data rewriting unit according to the present embodiment differs from the data rewriting unit according to the first embodiment shown in FIG. 5 in the functions of refresh zone detection part 22 and refresh execution part 23. Therefore, their configuration and features already described in detail above will not be repeated. The refresh zone detection part and the refresh execution part in the present embodiment will be referred to with reference numerals 22e and 23e, respectively.

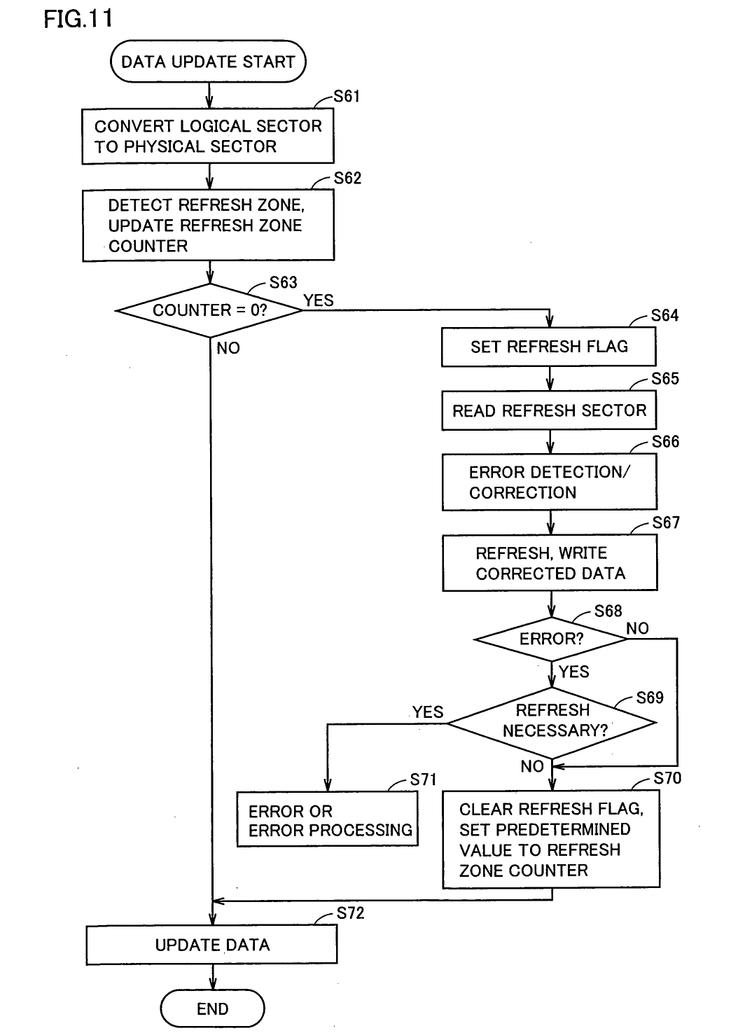

FIG. 11 is a flowchart for describing the operation procedure of the semiconductor storage device according to the sixth embodiment of the present invention. First, when data is written to a certain logical sector, logical/physical sector conversion part 21 converts the logical sector into a physical sector (S61).

Then, refresh zone detection part 22e detects a refresh zone which is to be the refresh target on the basis of the physical sector number converted by logical/physical sector conversion part 21, and decrements the value of the refresh zone counter corresponding to the refresh zone (S62).

Refresh execution part 23e determines whether the value of the refresh zone counter is “0” or not (S63). When the value of the refresh zone counter is not “0” (S63, No), no refresh is performed. Data update part 24 writes data to the sector (S72) to finish the processing.

When the value of the refresh zone counter is “0” (S63, Yes), refresh execution part 23e sets a refresh flag (S64), detects one sector in the refresh zone which is to be the refresh target, and reads ECC code 13 as well as data from the sector (S65).

Then, refresh execution part 23e performs error detection/correction of data by using ECC code 13 (S66), and refreshes the sector by writing the corrected data to the same sector (S67). In the case where an error generates after refresh is performed (S68, Yes), refresh execution part 23e determines whether the sector needs refresh or not, depending on whether the sector is defective or not on the basis of the non-defective sector code 14 read from the same sector (S69).

When the sector needs refresh (S69, Yes), error processing such as assigning the logical sector to another physical sector is performed (S71). On the other hand, when the sector does not need refresh (S71, No), refresh execution part 23e clears the refresh flag and sets a predetermined value to the refresh zone counter (S70). Data update part 24 writes data to the sector of the data writing target (S72) to finish the processing.

In steps S64 to S71, when the sector of the data writing target and the sector of the refresh target are the same, it is sufficient only to update the contents of refresh mark 15 and the data of the sector (S72), without refreshing this sector.

As described above, according to the semiconductor storage device of the present embodiment, every time data is written to a sector in the refresh zone for a predetermined number of times, one sector is refreshed in the refresh zone, and when an error generates, error processing is performed. Consequently, in addition to the effects described in the fifth embodiment, it also becomes possible to deal with errors which generate during refresh.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor storage device comprising:
a nonvolatile memory to which data is written in a sector unit; and
a data rewriting unit rewriting data in the nonvolatile memory, wherein
each sector in said nonvolatile memory includes: a data area into which data is stored; and a refresh mark into which information indicative of whether refresh has been performed or not is stored, and
said data rewriting unit includes a refresh execution unit referring to said refresh mark and determining whether the sector is refreshed or not, thereby executing the refresh.

2. The semiconductor storage device according to claim 1, wherein
said data rewriting unit further includes a refresh zone detection unit dividing a block of said nonvolatile memory into refresh zone units for executing refresh, and detecting the refresh zone including a sector of a writing target, and
said refresh execution unit refreshes the sector included in the refresh zone detected by said refresh zone detection unit every time data is written to a sector.

3. The semiconductor storage device according to claim 2, wherein
every time data is written to a sector, said refresh execution unit sequentially refreshes the sectors included in the refresh zone detected by said refresh zone detection unit, starting at a head sector or a final sector, and sets a first value in the refresh mark included in the sector, and
after completion of the refreshes for all the sectors included in said refresh zone, every time data is written to a sector, said refresh execution unit sequentially refreshes the sectors included in the refresh zone detected by said refresh zone detection unit, starting at the head sector or the final sector, and sets a second value different from the first value in the refresh mark included in the sector.

4. The semiconductor storage device according to claim 1, wherein
said data rewriting unit further includes a refresh zone detection unit dividing a block of said nonvolatile memory into refresh zone units for performing refresh, and detecting the refresh zone including a sector of a writing target, and
said refresh execution unit refreshes the sectors included in the refresh zone, every time data is written to a sector in the refresh zone detected by said refresh zone detection unit for a predetermined number of times.

5. The semiconductor storage device according to claim 4, wherein
every time data is written to the sector in the refresh zone detected by said refresh zone detection unit for the predetermined number of times, said refresh execution unit sequentially refreshes the sectors included in the refresh zone, starting at a head sector or a final sector, and sets a first value in the refresh mark included in the sector, and
after completion of the refreshes for all the sectors included in said refresh zone, every time data is written to the sector in the refresh zone for the predetermined number of times, said refresh execution unit sequentially refreshes the sectors included in the refresh zone, starting at the head sector or the final sector, and sets a second value different from the first value in the refresh mark included in the sector.

6. The semiconductor storage device according to claim 1, wherein
each sector in said nonvolatile memory further includes a data error detection/correction code, and
when refreshing the sector, said refresh execution unit writes data corrected by using said data error detection/correction code to the sector.

7. The semiconductor storage device according to claim 1, wherein
each sector in said nonvolatile memory further includes a non-defective sector code indicating whether the sector is defective or not, and
when refreshing the sector, said refresh execution unit suspends the refresh in the case where the sector has been found to be a defective sector by referring to said non-defective sector code.

8. The semiconductor storage device according to claim 7, wherein
in the case where the sector has been found to be a defective sector by referring to said non-defective sector code, said refresh execution unit refreshes another sector in said refresh zone.

9. The semiconductor storage device according to claim 7, wherein
in the case where an error generates after the refresh for the sector and the sector has been found to be a defective sector by referring to said non-defective sector code, said refresh execution unit suspends the refresh.
